(19) United States
(12) Patent Application Publication
(10) Pub. No.: US 2026/0052800 A1
(43) Pub. Date: Feb. 19, 2026

(54) CARTRIDGE INSPECTION ANCHORS

(71) Applicant: VueReal Inc., Waterloo (CA)

(72) Inventors: Gholamreza CHAJI, Kitchener (CA); Ehsanollah FATHI, Waterloo (CA)

(73) Assignee: VueReal Inc., Waterloo (CA)

(21) Appl. No.: 19/368,669

(22) Filed: Oct. 24, 2025

Related U.S. Application Data
(63) Continuation of application No. 17/785,964, now Pat. No. 12,477,862.
(60) Provisional application No. 62/950,708, filed on Dec. 19, 2019.

(51) Int. Cl. H10H 20/01

(52) U.S. Cl. CPC H10H 20/018

(57) ABSTRACT

The present disclosure deals with a method of integrating microdevices on a backplane using bonded pads. The process has a substrate having microdevices with bonding of selective microdevices through connecting pads on the microdevices and corresponding pads on the backplane, forming anchors and leaving the bonded selective set of microdevices on the backplane by separating the micro device substrate.

### CROSS REFERENCE TO RELATED APPLICATIONS

The present application is a continuation of U.S. patent application Ser. No. 17/785,964 filed Jun. 16, 2022, which is a 371 of PCT patent application number PCT/CA2020/051758 filed Dec. 18, 2020, which claims the benefit of U.S. patent application 62/950,708 filed Dec. 19, 2019. The contents of each of these prior applications are incorporated herein by reference in their entirety.

### FIELD OF THE INVENTION

The present disclosure relates to the integration of micro devices into system substrate.

### BRIEF SUMMARY

According to one embodiment, there may be provided a method of integrating micro devices on a backplane comprising; forming a micro device on a first substrate, the micro device covered by a dielectric layer, forming a release layer on top of the micro device, coupling a conductive layer to a micro device contact through an opening in the dielectric layer, bonding the micro device to a second substrate through a bonding layer, removing the micro device from the first substrate, patterning the dielectric layer to form anchors to hold the micro device, removing the release layer creating a void around part of the micro device; and transferring the micro device to a system substrate.

### BRIEF DESCRIPTION OF THE DRAWINGS

The foregoing and other advantages of the disclosure will become apparent upon reading the following detailed description and upon reference to the drawings.

FIG. 1A shows a microdevice that may comprise of different layers.

FIG. 1B shows the microdevice after the original substrate is removed.

FIG. 1C shows a top view of the microdevice after the original substrate is removed.

FIG. 1D shows the micro device after the release layer is removed.

The present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “microdevice” are used interchangeably. However, it is clear to one skilled in the art that the embodiments described here are independent of the device size.

A few embodiments of this description are related to integration micro-devices into a receiving substrate. The system substrate may comprise micro light emitting diodes (LEDs), Organic LEDs, sensors, solid state devices, integrated circuits, (micro-electro-mechanical systems) MEMS, and/or other electronic components.

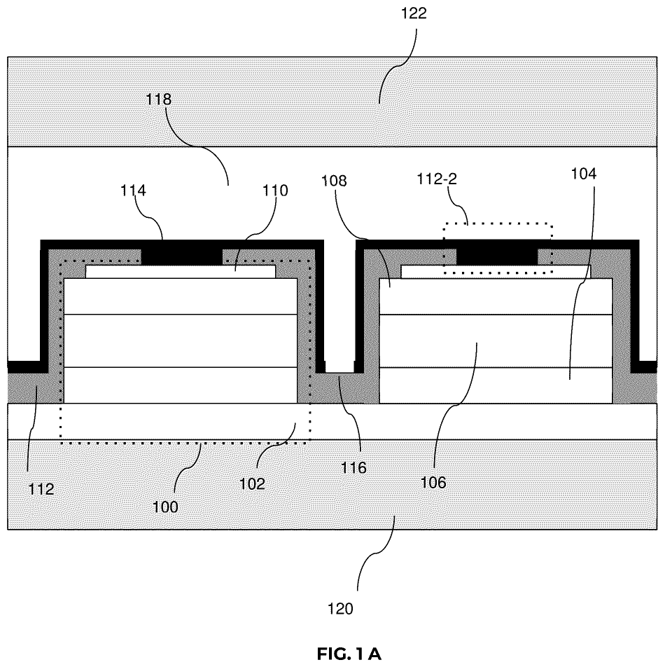

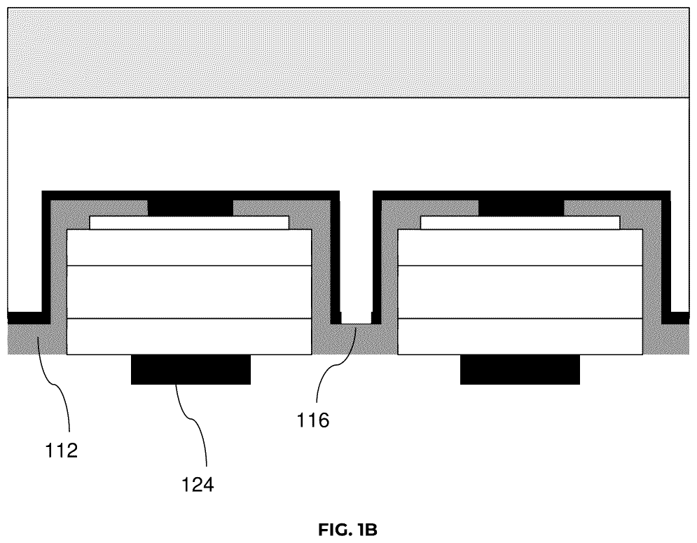

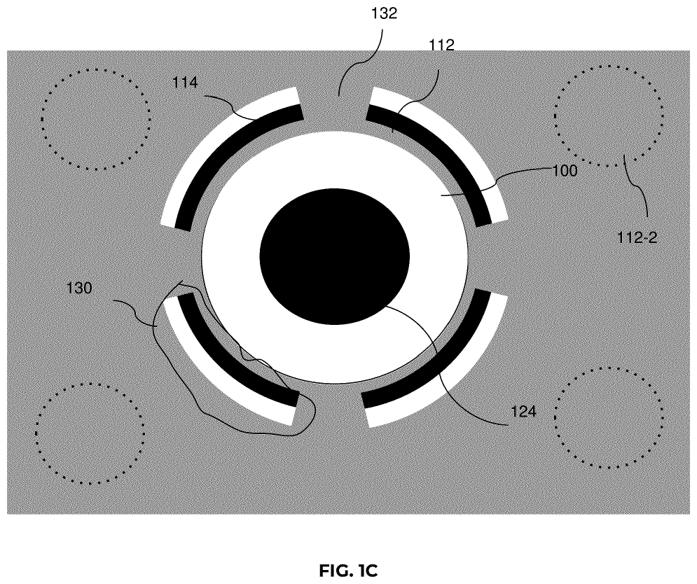

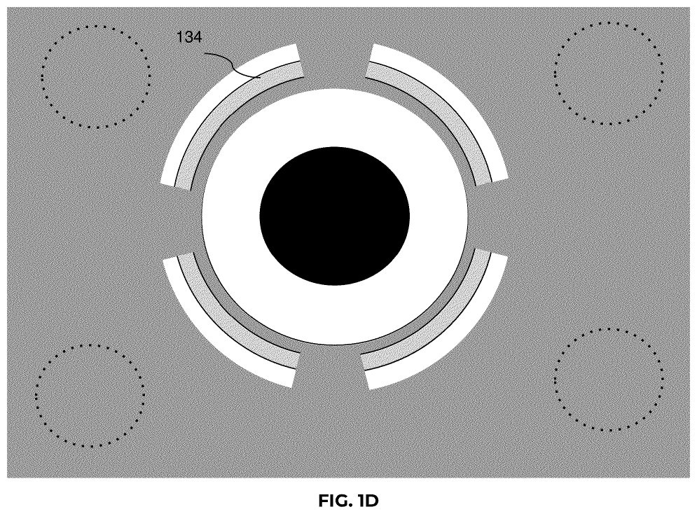

FIG. 1A shows a microdevice 100 that may comprise of different layers (the layers can be vertical or horizontal) such as a common unetched layer 102, a doped layer 104, an active layer 106, other doped layers 108 and a current spread layer 110. The device 100 may be formed on a substrate 120. The microdevice 100 is covered by a dielectric 112. The dielectric may have an opening 112-2 on top of the device 100 contacts. If the device has more than one contact, there can be more than one opening. A release layer can be formed on top of the microdevice before or after a conductive layer. The conductive layer 114 can be the same as the release layer. The conductive layer (and/or release layer) can have an opening 116 to provide access to the dielectric layer 112. The conductive layer 114 can be coupled to the microdevice contact through the opening in the dielectric 112-2. The microdevice is bonded to another substrate 122 using a bonding layer(s) 118. If the microdevice 100 has more than one contact, the conductive layer can be patterned to provide separate conductive traces coupled to separate microdevice contact.

FIG. 1B shows the microdevice 100 after the original substrate 120 is removed and the common layer 102 (if it exists) is removed. Other contacts 124 may be formed on the exposed surface of the microdevice. A layer can be formed before, after or part of the new contacts 124 connecting at least one microdevice. The new contact(s) and the conductive layer 114 test the performance or defects of the microdevice. The dielectric layer 112 can be patterned to prepare anchors holding the microdevice 100 in place.

FIG. 1C shows a top view of the microdevice 100 demonstrated in FIG. 1B. This figure shows on patterning configuration. The pattern 130 in the dielectric layer forms anchors 132 that hold the device in place.

FIG. 1D shows an exemplary embodiment, where the release layer is removed. The release layer can be the same as conductive layer. The removal of the release layer creates a void 134 around the microdevice.

The microdevice then can be transferred to a system substrate. The anchors will release the LED due to the transfer process.

The present invention outlines a method to transfer a microdevice, which comprise forming a micro device on a first substrate, the microdevice covered by a dielectric layer, forming a release layer on top of the microdevice, coupling a conductive layer to a microdevice contact through an opening in the dielectric layer, bonding the microdevice to a second substrate through a bonding layer, removing the microdevice from the first substrate, patterning the dielectric layer to form anchors to hold the micro device, removing the release layer creating a void around part of the microdevice, and transferring the micro device to a system substrate. The method further comprises wherein the conductive layer is the release layer. The method further comprises, wherein the microdevice has more than one contact. The method further comprise wherein the release layer is formed before or after the conductive layer. The method further comprises, wherein the dielectric layer has more than one openings on top of the microdevice contacts. The method further comprises, wherein the conductive layer has an opening to access the dielectric layer. The method further comprises, wherein the microdevice comprises of different layers such as a common unetched layer, a doped layer, an active layer, other doped layers, a current spread layer, and wherein further the different layers can be vertical or horizontal. The method further comprises, wherein additional contacts are formed on an exposed surface of the micro device once the first substrate is removed and wherein further wherein the additional contacts and the conductive layer test a performance and defects of the microdevice.

In some aspects, a method to transfer a microdevice is described. The method may include forming a microdevice on a first substrate, where the microdevice is covered by a dielectric layer. The method may further include forming a release layer on top of the microdevice. The method may also include coupling a conductive layer to a microdevice contact through an opening in the dielectric layer. The method may further include bonding the microdevice to a second substrate through a bonding layer and removing the microdevice from the first substrate. The method may include patterning the dielectric layer to form anchors that hold the microdevice. The method may further include removing the release layer to create a void around part of the microdevice. The method may also include transferring the microdevice to a system substrate.

In some implementations, the conductive layer may be the release layer.

In some implementations, the microdevice may have more than one contact.

In some implementations, the release layer may be formed before or after the conductive layer.

In some implementations, the dielectric layer may have more than one opening on top of the microdevice contacts.

In some implementations, the conductive layer may have an opening to access the dielectric layer.

In some implementations, the microdevice may include different layers such as a common unetched layer, a doped layer, an active layer, other doped layers, and a current spread layer.

In some implementations, the different layers may be arranged vertically or horizontally.

In some implementations, additional contacts may be formed on an exposed surface of the microdevice once the first substrate is removed.

In some implementations, the additional contacts and the conductive layer may be used to test a performance and defects of the microdevice.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of the invention as defined by the appended claims.

1. A method to transfer a microdevice, the method comprising:
coupling a conductive layer to a microdevice contact through an opening in a dielectric layer;
bonding the microdevice to a second substrate;
removing the microdevice from a first substrate; and
removing a release layer formed on the microdevice creating a void.
